(19) United States
(12) Patent Application Publication
(10) Pub. No.: US 2014/0283381 A1
(43) Pub. Date: Sep. 25, 2014

(54) METHOD OF MOUNTING ELECTRONIC COMPONENT

(71) Applicant: FUJITSU LIMITED, Kawasaki-shi (JP)

(72) Inventor: Yoko MURATA, Kawasaki (JP)

(73) Assignee: FUJITSU LIMITED, Kawasaki-shi (JP)

(21) Appl. No.: 14/183,725

(22) Filed: Feb. 19, 2014

(30) Foreign Application Priority Data
Mar. 22, 2013 (JP) 2013-060964

(51) Int. Cl. H05K 3/30

(52) U.S. Cl. CPC H05K 3/306
USPC 29/837

(57) ABSTRACT

A method of mounting an electronic component includes applying solder paste to a through-hole of a printed board on which an electronic component is mounted, placing the electronic component on the printed board with a restricting member that restricts a terminal of the electronic component from entering the through-hole, the restricting member being sandwiched between the electronic component and the printed board, performing reflow at a temperature at which the restricting member melts, and welding the terminal in the through-hole with the solder paste.

### CROSS-REFERENCE TO RELATED APPLICATION

This application is based upon and claims the benefit of priority of the prior Japanese Patent Application No. 2013-060964, filed on Mar. 22, 2013, the entire contents of which are incorporated herein by reference.

### FIELD

The embodiment discussed herein is related to a method of mounting an electronic component.

### BACKGROUND

Electronic devices such as information and communication devices, cellular phones, personal computers, and consumer electronics have a printed board on which various electronic components are mounted. Technologies of mounting an electronic component on a printed board include surface mount technology (SMT), insert mount technology (IMT), and press fit. SMT is used, for example, in a case where a semiconductor device having a ball grid array (BGA) is mounted on a printed circuit. IMT and press fit are used at a point to which physical stress relatively tends to be applied, for example, a back board to which many mother boards are connected in a server or communication device, or a connecting part of a cable connector or the like (see, for example, Japanese Unexamined Utility Model Publication No. 04-94775). In IMT, performing reflow with a pin-like terminal passed through a through-hole is sometimes called pin reflow or pin through reflow.

When solder paste is applied to a through-hole of a printed board and then an electronic component is placed on the printed board, the solder paste applied to the through-hole is displaced by a terminal of the electronic component. When reflow is performed, the molten solder paste may not spread throughout the space between the terminal and the through-hole.

It is an object of the present disclosure to provide a method of mounting an electronic component that improves the bonding reliability in welding a terminal of an electronic component to a through-hole with solder paste applied to the through-hole.

### SUMMARY

According to an aspect of the invention, a method of mounting an electronic component includes applying solder paste to a through-hole of a printed board on which an electronic component is mounted; placing the electronic component on the printed board with a restricting member that restricts a terminal of the electronic component from entering the through-hole, the restricting member being sandwiched between the electronic component and the printed board; and performing reflow at a temperature at which the restricting member melts, and welding the terminal in the through-hole with the solder paste.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is an example of a process flowchart of a method of mounting an electronic component;

FIG. 2 is an example of a view illustrating a state where solder paste is applied to through-holes of a printed board on which an electronic component is mounted;

FIG. 3 is an example of a view illustrating a state where the electronic component is placed on the printed board;

FIG. 4 is an example of a view illustrating a state where terminals are welded in the through-holes with the solder paste;

FIG. 5 is an example of a view illustrating a state where the electronic component is placed on the printed board without restricting members;

FIG. 6 is an example of a view illustrating the state of solder paste in the case where the electronic component is mounted on the printed board without the restricting members;

FIG. 7 is an example of a view illustrating the printed board in which the amount of solder paste applied to the through-holes is increased;

FIG. 8 is a modification of a view illustrating a state where the electronic component is placed on a printed board;

FIG. 9 is an example of a view illustrating a printed board having through-holes provided in parts thereof corresponding to the restricting members;

FIG. 10 is an example of a view illustrating a state where the electronic component is placed on the printed board having through-holes provided in parts thereof corresponding to the restricting members;

FIG. 11 is an example of a view illustrating a state where the molten restricting members has entered the through-holes;

FIG. 12 is an example of a view illustrating an electronic component on which many restricting members as terminals for electrical connection are arrayed;

FIG. 13 is an example of a view illustrating a state where the electronic component on which restricting members as terminals for electrical connection are arrayed is being mounted on a printed board;

FIG. 14 is an example of a view illustrating a state where the electronic component on which restricting members as terminals for electrical connection are arrayed has been mounted on the printed board;

FIG. 15 is an example of a view illustrating an electronic component provided with standoffs in addition to terminals and restricting members;

FIG. 16 is an example of a view illustrating the electronic component provided with standoffs in addition to terminals and restricting members is being mounted on a printed board;

FIG. 17 is an example of a view illustrating a state where the electronic component provided with standoffs in addition to terminals and restricting members is placed on the printed board;

FIG. 18 is an example of a view illustrating a state where reflow is being performed on the electronic component provided with standoffs in addition to terminals and restricting members; and

FIG. 19 is an example of a view illustrating a state where the electronic component provided with standoffs in addition to terminals and restricting members has been mounted on the printed board.

### DESCRIPTION OF EMBODIMENT

The embodiment is described below. The embodiment described below is provided for illustrative purposes only, and does not define the technical scope of the present disclosure.

### Embodiment of Method of Mounting Electronic Component

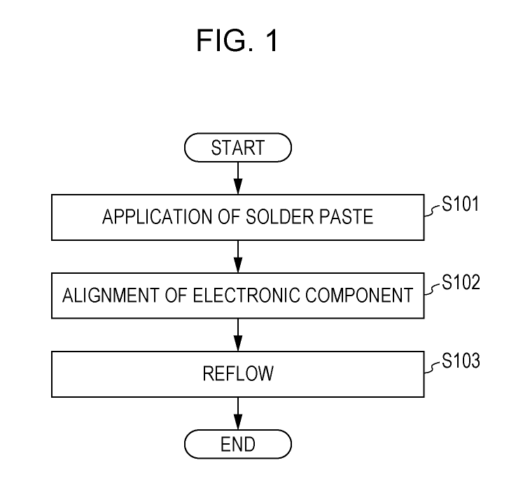

FIG. 1 is an example of a process flowchart of a method of mounting an electronic component. The method of mounting an electronic component according to the embodiment is described below with reference to the process flowchart of FIG. 1.

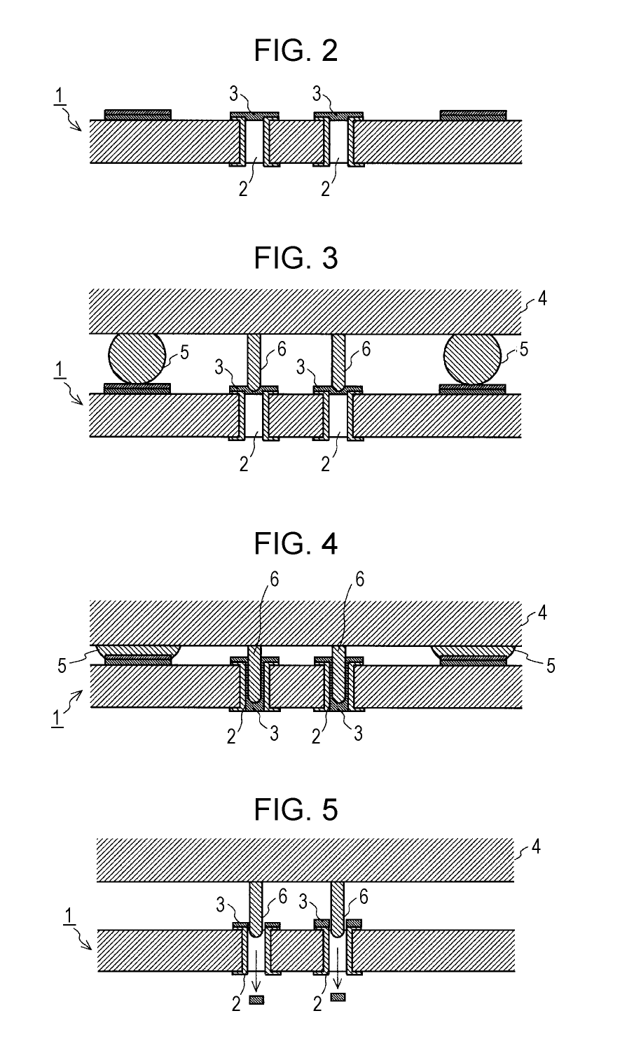

In the embodiment, first, solder paste is applied to through-holes of a printed board on which an electronic component is mounted (S101). FIG. 2 is an example of a view illustrating a state where solder paste is applied to through-holes of a printed board on which an electronic component is mounted. When solder paste 3 is applied to through-holes 2 of a printed board 1 on which an electronic component is mounted, for example, the solder paste 3 is applied so as to cover the opening parts of the through-holes 2. If the solder paste 3 is applied so as to cover the opening parts of the through-holes 2, the solder paste 3 easily spread throughout the spaces between the through-holes 2 and the terminals of the electronic component at the time of reflow. The application of the solder paste 3 to the through-holes 2 may be performed, for example, by covering the surface of the printed board 1 with a mask having holes formed in parts thereof corresponding to the through-holes 2, applying solder paste on the mask, then performing squeegeeing, and removing the mask.

When the solder paste 3 is applied to the through-holes 2, the solder paste 3 may not be applied so as to cover the opening parts of the through-holes 2. The solder paste 3 may be applied so as to cover only parts of the opening parts of the through-hole 2, or may be applied to the insides of the through-holes 2.

In the embodiment, next, an electronic component is placed on the printed board 1 (S102), with restricting members that restrict terminals of the electronic component from entering the through-holes 2 sandwiched between the electronic component and the printed board 1 (S102). FIG. 3 is an example of a view illustrating a state where the electronic component is placed on the printed board. When the electronic component 4 is placed on the printed board 1, for example, the electronic component 4 is placed on the printed board 1, with restricting members 5 that restrict terminals 6 of the electronic component 4 from entering the through-holes 2 sandwiched between the electronic component 4 and the printed board 1. When the electronic component 4 is placed on the printed board 1, for example, the relative positional relationship between the electronic component 4 and the printed board 1 is adjusted so that the terminals 6 are aligned with the positions of the through-holes 2. Alignment may be performed with a high degree of accuracy, for example, by adjustment of the amount of movement of a mounter that handles the electronic component 4, or fine adjustment using guides, such as holes or marks, formed in or on the electronic component 4 or the printed board 1. Insertion guides used to insert the terminals 6 into the through-holes 2 may be, for example, pin-like terminals and through-holes provided for guiding, or various protrusions protruding from the electronic component 4 and holes provided in the printed board 1.

The restricting members 5 are members formed of a hot-melt material capable of being melted by reflow. For example, members formed of solder may be used. The restricting members 5 may have any form. For example, when the electronic component 4 includes not only pin-like connection terminals for IMT but also solder ball connection terminals for SMT, the restricting members 5 may be solder balls. In this case, the restricting members 5 may be formed in the same process as the formation of solder balls as connection terminals. However, the restricting members 5 are not limited to those in the form of solder balls, and may be, for example, those having the same form as so-called standoffs used to keep an electronic component at a distance from the surface of a printed board or the like.

The restricting members 5 may be members welded to the electronic component 4, may be members welded to the printed board 1, or may be members not welded to the printed board 1 or the electronic component 4.

The restricting members 5 are formed so as to restrict the terminals 6 from entering the through-holes 2 such that the tips of the terminals 6 are kept before the opening parts of the through-holes 2. Therefore, in a state where the restricting members 5 restrict the entrance of the terminals 6, it is unlikely that the solder paste 3 applied to the through-holes 2 is displaced by the terminals 6. When the solder paste 3 is applied so as to cover the opening parts of the through-holes 2, the restricting members 5 may restrict the entrance of the terminals 6 such that the tips of the terminals 6 are kept in contact with the solder paste 3 covering the opening parts of the through-holes 2. In this case, when the solder paste 3 is melted by reflow, the solder paste 3 is easily welded to the terminals 6. The position at which the terminals 6 are kept may be changed by adjusting the height of the restricting members 5.

Although the restricting members 5 are in contact with pad-like members provided on the printed board 1 in FIG. 3 and FIG. 4, the pad-like members may be omitted.

In the embodiment, next, reflow is performed at a temperature at which the restricting members 5 melt, and the terminals 6 are welded in the through-holes 2 with the solder paste 3 (S103). FIG. 4 is an example of a view illustrating a state where the terminals are welded in the through-holes with the solder paste. Reflow may be performed, for example, by passing the printed board 1 on which the electronic component 4 is placed through a tunnel-like oven provided with a heat source such as a sheathed heater or an infrared lamp, and performing preheating, main heating, cooling, and so forth. When reflow is performed on the printed board 1 on which the electronic component 4 is placed, the solder paste 3 and the restricting members 5 melt. As the restricting members 5 melt, the electronic component 4 supported by the restricting members 5 lowers, and the terminals 6 of the electronic component 4 enter the through-holes 2. When the restricting members 5 melt and the terminals 6 of the electronic component 4 enter the through-holes 2, the solder paste 3 is already melted by reflow, and has sufficient wettability to the surfaces of the through-holes 2 and the surfaces of the terminals 6. Therefore, when the restricting members 5 melt and the terminals 6 of the electronic component 4 enter the through-holes 2, the molten solder paste 3 spreads into the spaces between the terminals 6 and the through-holes 2 and fills the spaces. The solder paste 3 spread into the spaces between the terminals 6 and the through-holes 2 hardens when cooled, and welds the terminals 6 in the through-holes 2.

According to the embodiment, the restricting members 5 are used, and therefore when the electronic component 4 is placed on the printed board 1, the entrance of the terminals 6 into the through-holes 2 is restricted. Therefore, when the electronic component 4 is placed on the printed board 1, it is unlikely that the solder paste 3 applied to the through-holes 2 is displaced from the through-holes 2.

The restricting members 5 may be formed of any hot-melt material capable of being melted by reflow. For example, the restricting members 5 may be formed of the same material as the solder paste 3. If the restricting members 5 are formed of the same material as the solder paste 3, the restricting members 5 and the solder paste 3 melt at almost the same temperature at the time of reflow. Therefore, when the restriction of the entrance of the terminals 6 into the through-holes 2 by the restricting members 5 is lifted, it is unlikely that the solder paste 3 is displaced from the through-holes 2. For example, if a hierarchy of temperatures is provided such that when reflow is performed, the solder paste 3 liquefies first, and then the restricting members 5 liquefy, the terminals 6 easily enter the through-holes 2.

FIG. 5 is an example of a view illustrating a state where the electronic component is placed on the printed board without the restricting members. When the electronic component 4 is placed on the printed board 1 without the restricting members 5, there are no devices that restrict the terminals 6 of the electronic component 4 from entering the through-holes 2, and therefore the solder paste 3 applied to the through-holes 2 may be displaced by the terminals 6 of the electronic component 4.

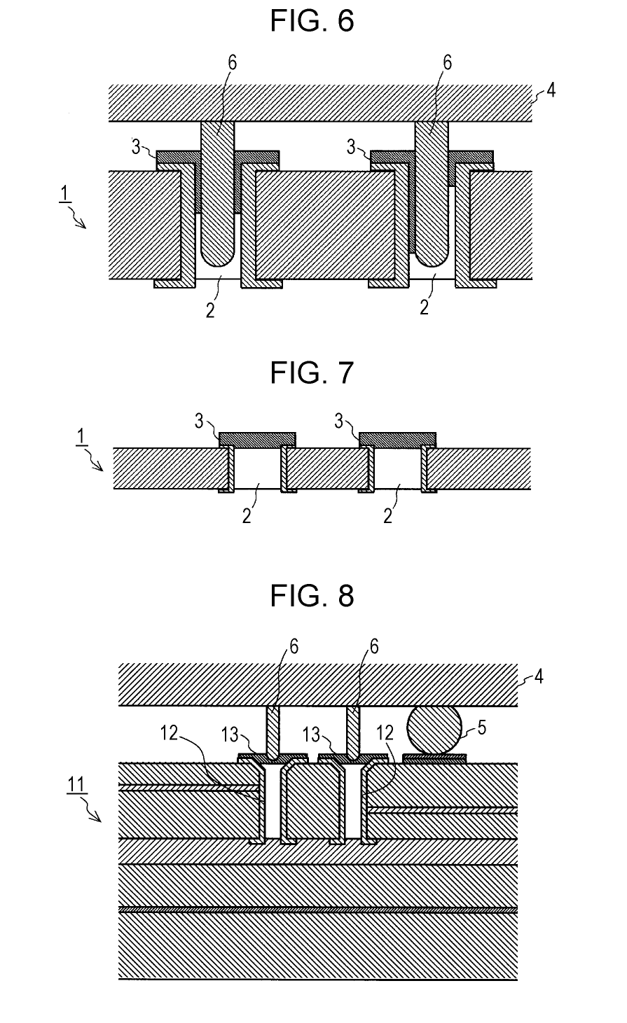

FIG. 6 is an example of a view illustrating the state of solder paste in the case where the electronic component is mounted on the printed board without the restricting members. If the electronic component 4 is placed on the printed board 1 without the restricting members 5, the solder paste 3 applied to the through-holes 2 is displaced by the terminals 6 of the electronic component 4, and the amount of solder paste 3 that welds the terminals 6 may become insufficient. If reflow is performed in a state where the amount of solder paste 3 that welds the terminals 6 is insufficient, the molten solder paste 3 may not spread throughout the spaces between the terminals 6 and the through-holes 2. For example, as illustrated in FIG. 6, if the solder paste 3 does not spread throughout the spaces between the terminals 6 and the through-holes 2, the increase in electrical resistance and the lack of bonding strength may be caused.

Therefore, it is conceivable to increase the amount of solder paste applied to the through-holes so that the molten solder paste spreads throughout the spaces between the terminals and the through-holes. FIG. 7 is an example of a view illustrating the printed board in which the amount of solder paste applied to the through-holes is increased. The amount of solder paste 3 applied to the through-holes 2 may be adjusted by changing the size of lands surrounding the through-holes, or by increasing or reducing the thickness of the solder paste 3. When the amount of solder paste applied to the through-holes is increased, the solder paste 3 melted by reflow may flow to the peripheries of the through-holes 2 and may come into contact with the neighboring through-holes 2 or the like. Therefore, when it is desired to increase the amount of solder paste applied to the through-holes, the distance between the through-holes 2 is increased as illustrated in FIG. 7, and it is difficult to cope with the increase in wiring density.

If the mounting method of the embodiment using restricting members is used, it is unlikely that the solder paste is displaced from the through-holes. Therefore, even if the amount of solder paste is reduced, the solder paste may be spread throughout the spaces between the terminals and the through-holes. Therefore, if the electronic component is mounted using the restricting members, the possibility that the increase in electrical resistance and the lack of bonding strength between the terminals and the through-holes are caused may be reduced compared to the case where the restricting members are not used. When the amount of solder paste is reduced, reducing the clearance between the through-holes and the terminals according to the reduction of solder paste facilitates the filling of the spaces between the through-holes and the terminals with solder paste.

If the electronic component is mounted using the restricting members, the amount of solder paste applied to the through-holes may be reduced compared to the case where the restricting members are not used. Therefore, if the electronic component is mounted using the restricting members, the distance between the through-holes and the distance between the terminals may be reduced compared to the case where the restricting members are not used, and the length of the terminals may be reduced. Therefore, if the method of mounting an electronic component according to the above embodiment is used, it may be easy to cope with the increase in wiring density compared to the case where the restricting members are not used, and application, for example, to a small connector is possible. In addition, if the method of mounting an electronic component according to the above embodiment is used, it may be easy to cope with the reduction in length of terminals compared to the case where the restricting members are not used, and application, for example, to a high-speed transmission connector is possible.

First Modification

The method of mounting an electronic component according to the above embodiment is also applicable to the following printed board. FIG. 8 is a modification of a view illustrating a state where the electronic component is placed on a printed board.

The method of mounting an electronic component according to the above embodiment is also applicable, for example, to a case where, as illustrated in FIG. 8, the terminals 6 of the electronic component 4 are inserted into through-holes 12 that do not extend all the way through a printed board 11, and the electronic component 4 is mounted. When the restricting members 5 support the electronic component 4, it is unlikely that the solder paste 13 applied to the through-holes 12 is displaced by the terminals 6 and falls into the through-holes 12. If the mounting method using the restricting members 5 is used, it is unlikely that the solder paste 13 is displaced from the through-holes 12. Therefore, even if the amount of the solder paste 13 is reduced, the solder paste 13 may be spread throughout the spaces between the terminals 6 and the through-holes 12 by reflow. Therefore, if the electronic component 4 is mounted on the printed board 11 by the method of mounting an electronic component according to the above embodiment, the possibility that the increase in electrical resistance and the lack of bonding strength between the terminals 6 and the through-holes 12 are caused may be reduced compared to the case where the restricting members 5 are not used.

Second Modification

The method of mounting an electronic component according to the above embodiment is also applicable, for example, to a case where, as illustrated in FIG. 8, the electronic component 4 is mounted on a printed board 11 having through-holes 12 the opening parts of which become gradually wider outward. When the restricting members 5 support the electronic component 4, it is unlikely that the solder paste 13 applied to the through-holes 12 is displaced by the terminals 6 of the electronic component 4. Therefore, if the mounting method using the restricting members is used, it is unlikely that the solder paste 13 applied to the through-holes 12 is displaced by the terminals 6 and falls into the through-holes 12 even if the opening parts of the through-holes 12 become gradually wider outward. Since it is unlikely that the solder paste 13 is displaced from the through-holes 12, the solder paste 13 melted by reflow may be spread throughout the spaces between the terminals 6 and the through-holes 12 even if the amount of the solder paste 13 is reduced. Therefore, if the electronic component 4 is mounted by the method of mounting an electronic component according to the above embodiment, the possibility that the increase in electrical resistance and the lack of bonding strength between the terminals 6 and the through-holes 12 are caused may be reduced compared to the case where the restricting members 5 are not used. Since the opening parts of the through-holes 12 become gradually wider outward, the terminals 6 may be easily inserted into the through-holes 12.

When the opening parts of the through-holes 12 become gradually wider outward, the terminals 6 may be easily inserted into the through-holes 12 even if the clearance between the through-holes 12 and the terminals 6 is small.

Although FIG. 8 depicts through-holes 12 that do not extend all the way through a printed board 11 and the opening parts of which become gradually wider outward, the method of mounting an electronic component according to the above embodiment is not limited to the application to a printed board that combines the first modification and the second modification. The method of mounting an electronic component according to the above embodiment is also applicable, for example, to a printed board provided with through-holes that extend all the way through the printed board and the opening parts of which become gradually wider outward, or a printed board provided with through-holes that do not extend all the way through the printed board and the opening parts of which do not become gradually wider outward.

Third Modification

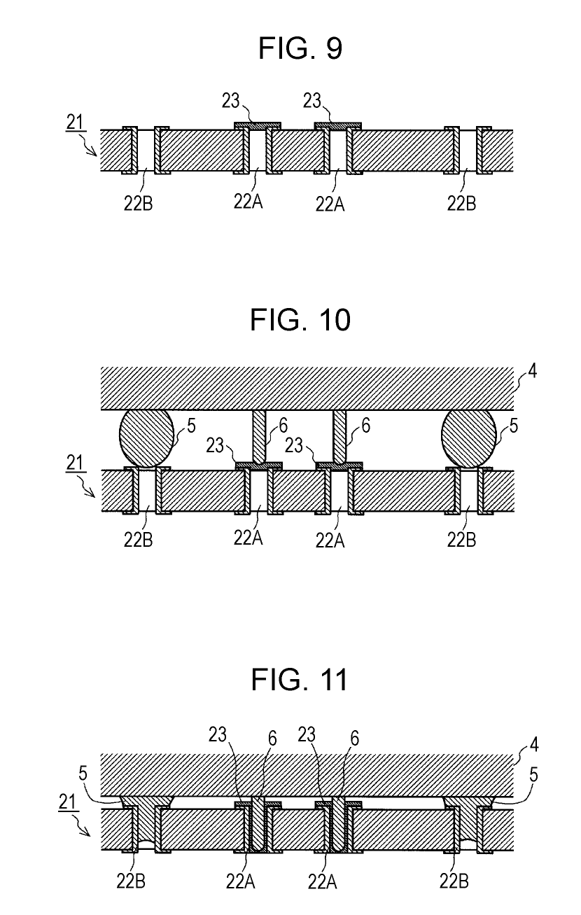

The method of mounting an electronic component according to the above embodiment is also applicable, for example, to a case where the electronic component is mounted on a printed board having through-holes provided in parts thereof corresponding to the restricting members. FIG. 9 is an example of a view illustrating a printed board having through-holes provided in parts thereof corresponding to the restricting members. When the method of mounting an electronic component according to the above embodiment is applied to a printed board 21 having through-holes 22B provided in parts thereof corresponding to the restricting members, solder paste 23 is applied, for example, as illustrated in FIG. 9, so as to cover the opening parts of through-holes 22A corresponding to terminals (S101).

FIG. 10 is an example of a view illustrating a state where the electronic component is placed on the printed board having through-holes provided in parts thereof corresponding to the restricting members. When the electronic component 4 is placed on the printed board 21 having through-holes 22B provided in parts thereof corresponding to the restricting members 5, the electronic component 4 is placed on the printed board 21, for example, such that the terminals 6 are aligned with the positions of the through-holes 22A (S102). The restricting members 5 are sandwiched between the electronic component 4 and the printed board 21 in positions where there are the through-holes 22B.

Next, reflow is performed at a temperature at which the restricting members 5 melt, and the terminals 6 are welded in the through-holes 22A with the solder paste 23 (S103). At this time, since reflow is performed at a temperature at which the restricting members 5 melt, the molten restricting members 5 enter the through-holes 22B. FIG. 11 is an example of a view illustrating a state where the molten restricting members has entered the through-holes. When reflow is performed on the printed board 21 on which the electronic component 4 is placed, the solder paste 23 and the restricting members 5 melt. As the restricting members 5 melt, the electronic component 4 supported by the restricting members 5 lowers, and the terminals 6 of the electronic component 4 enter the through-holes 22A, and the molten restricting members 5 enters the through-holes 22B. Therefore, the printed board 21 provided with the through-holes 22B may reduce the possibility that the molten restricting members 5 spread on the surface of the printed board 21 compared to a printed board without the through-holes 22B.

Fourth Modification

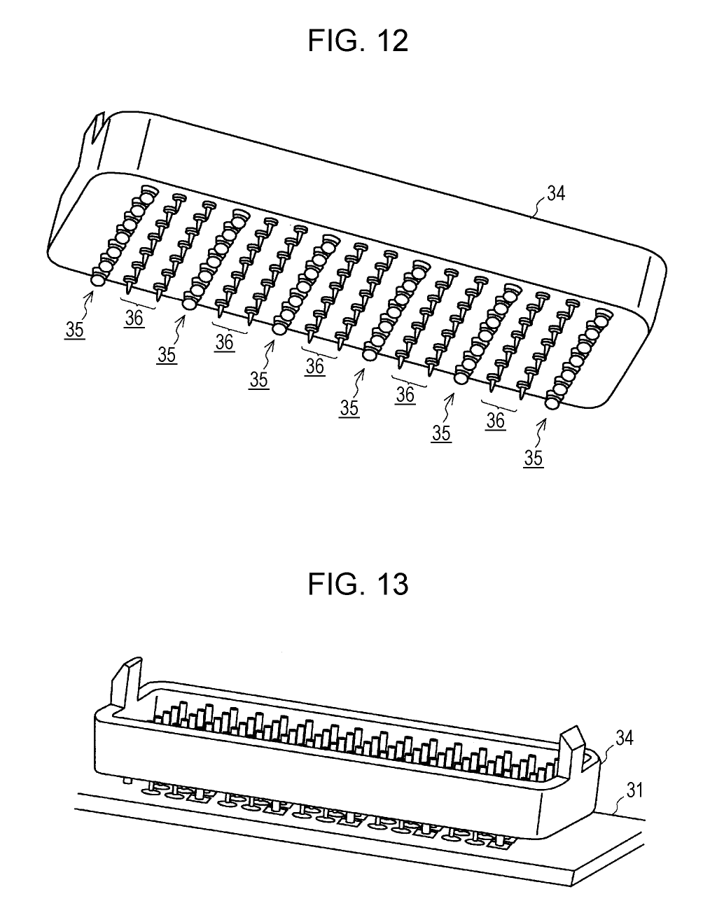

The restricting members may double, for example, as terminals for transmission of electric signals or electrical connection such as grounding. FIG. 12 is an example of a view illustrating an electronic component on which many restricting members as terminals for electrical connection are arrayed. The electronic component 34 illustrated in FIG. 12 has an array of restricting members 35 as terminals for electrical connection and pin-like terminals 36. Therefore, in the electronic component 34, the restricting members 35 are bonded using SMT, and the terminals 36 are bonded using IMT.

FIG. 13 is an example of a view illustrating a state where the electronic component on which restricting members as terminals for electrical connection are arrayed is being mounted on a printed board. When the electronic component 34 on which restricting members 35 as terminals for electrical connection are arrayed is mounted on a printed board 31, the relative positional relationship between the electronic component 34 and the printed board 31 is adjusted so that the positions of the restricting members 35 and the terminals 36 are aligned with the positions of electrode pads and through-holes of the printed board 31.

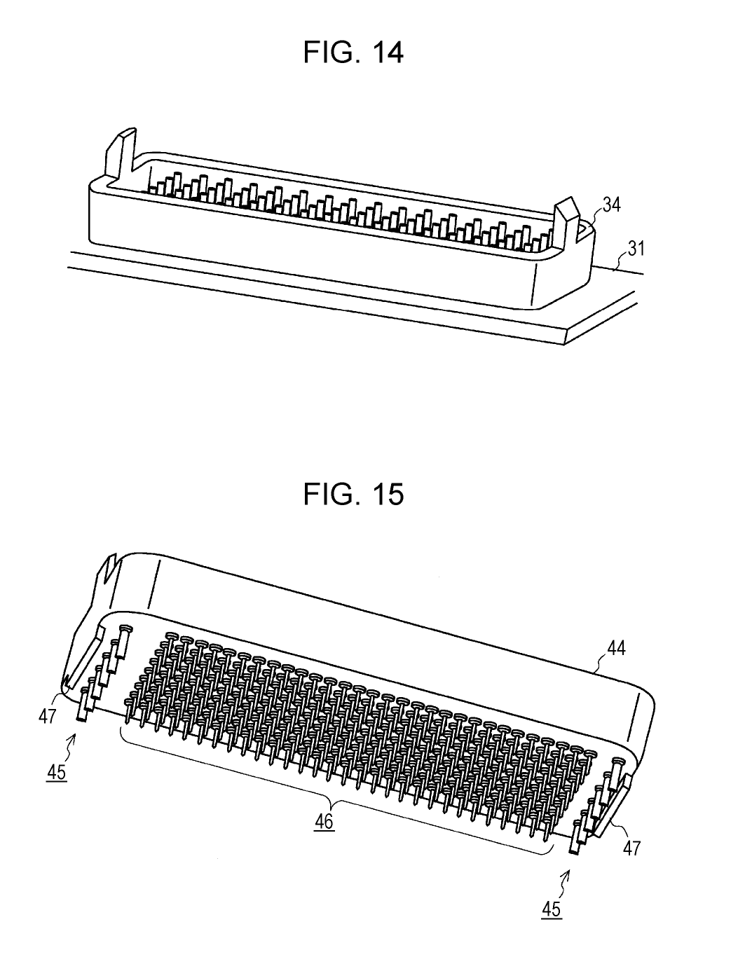

FIG. 14 is an example of a view illustrating a state where the electronic component on which restricting members as terminals for electrical connection are arrayed has been mounted on the printed board. After the relative positional relationship between the electronic component 34 and the printed board 31 is adjusted, reflow is performed on the printed board 31 on which the electronic component 34 is placed, and the solder paste applied to the through-holes and the restricting members are melted. As the restricting members 35 melt, the electronic component 34 supported by the restricting members 35 lowers, and the terminals 36 of the electronic component 34 enter the through-holes of the printed board 31, and the terminals 36 are welded to the through-holes 32. The molten restricting members 35 are welded to the electrode pads of the printed board 31.

In the fourth modification, when the electronic component 34 is placed on the supporting surface 31, the restricting members 35 support the electronic component 34. Therefore, if the method of mounting an electronic component according to the above embodiment is applied to a case where an electronic component 34 on which restricting members 35 as terminals for electrical connection are arrayed is mounted on a printed board 31, the possibility that the solder paste applied to the through-holes is displaced from the through-holes may be reduced, and the increase in electrical resistance and the lack of bonding strength may be suppressed.

Fifth Modification

The method of mounting an electronic component according to the above embodiment may be applied to a case where an electronic component provided with standoffs is mounted on a printed board. FIG. 15 is an example of a view illustrating an electronic component provided with standoffs in addition to terminals and restricting members. The electronic component 44 illustrated in FIG. 15 includes pin-like terminals 46 for electrical connection of the electronic component 44, pin-like restricting members 45 for supporting the electronic component 44, and standoffs 47 that keep the electronic component 44 at a distance from the surface of a printed board even at the time of reflow during which solder paste and the restricting members 45 melt.

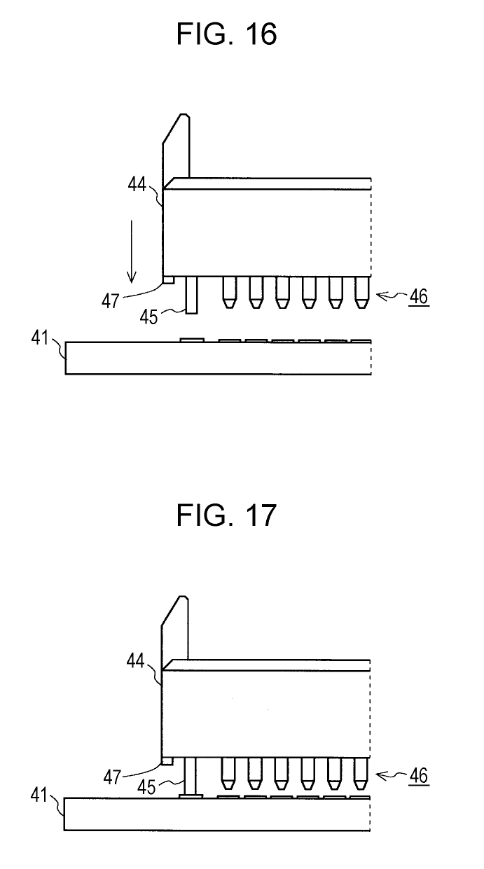

FIG. 16 is an example of a view illustrating the electronic component provided with standoffs in addition to terminals and restricting members is being mounted on a printed board. When the electronic component 44 is mounted on a printed board 41, the relative positional relationship between the electronic component 44 and the printed board 41 is adjusted so that the positions of the terminals 46 are aligned with through-holes of the printed board 41.

FIG. 17 is an example of a view illustrating a state where the electronic component provided with standoffs in addition to terminals and restricting members is placed on the printed board. Since the electronic component 44 is provided with restricting members 45, in the stage before reflow, the entrance of the terminals 46 into the through-holes is restricted, and the standoffs 47 are away from the printed board 41.

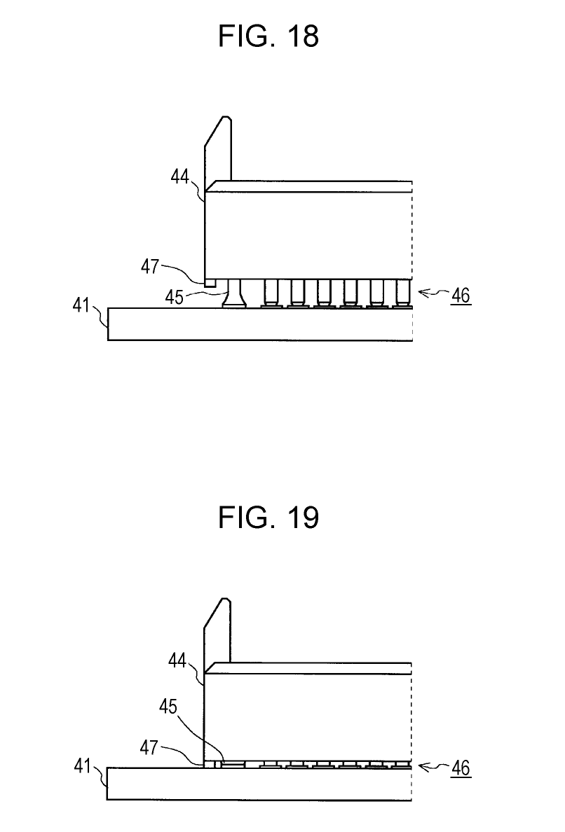

FIG. 18 is an example of a view illustrating a state where reflow is being performed on the electronic component provided with standoffs in addition to terminals and restricting members. As the restricting members 45 start to be melted by reflow, the electronic component 44 supported by the restricting members 45 starts to lower. When the restricting members 45 melt and the terminals 46 of the electronic component 44 enter the through-holes, the solder paste applied to the through-holes is already melted by reflow, and has sufficient wettability to the surfaces of the through-holes and the surfaces of the terminals 46. Therefore, when the restricting members 45 melt and the terminals 46 of the electronic component 44 enter the through-holes, the molten solder paste spreads into the spaces between the terminals 46 and the through-holes and fills the spaces.

FIG. 19 is an example of a view illustrating a state where the electronic component provided with standoffs in addition to terminals and restricting members has been mounted on the printed board. When the restricting members 45 have been completely melted by reflow, the standoffs 47 of the electronic component 44 come into contact with the printed board 41. When the standoffs 47 of the electronic component 44 come into contact with the printed board 41, the lowering of the electronic component 44 stops. Therefore, the electronic component 44 is mounted on the printed board 41 with a space between the electronic component 44 and the printed board 41. If the method of mounting an electronic component according to the above embodiment is applied to a case where an electronic component provided with standoffs in addition to terminals and restricting members is mounted on a printed board, the possibility that the solder paste applied to the through-holes is displaced from the through-holes may be reduced, and the increase in electrical resistance and the lack of bonding strength may be suppressed.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method of mounting an electronic component comprising:
applying solder paste to a through-hole of a printed board on which an electronic component is mounted;
placing the electronic component on the printed board with a restricting member that restricts a terminal of the electronic component from entering the through-hole, the restricting member being sandwiched between the electronic component and the printed board; and
performing reflow at a temperature at which the restricting member melts, and welding the terminal in the through-hole with the solder paste.

2. The method of mounting an electronic component according to claim 1, wherein in the applying solder paste to the through-hole, the solder paste is applied so as to cover the opening part of the through-hole.

3. The method of mounting an electronic component according to claim 1, wherein the restricting member is formed so as to restrict the terminal from entering the through-hole such that the tip of the terminal is kept before the opening part of the through-hole.

4. The method of mounting an electronic component according to claim 1, wherein in the applying solder paste to the through-hole, the solder paste is applied so as to cover the opening part of the through-hole, and wherein the restricting member is formed so as to restrict the terminal from entering the through-hole such that the tip of the terminal is kept in contact with the solder paste covering the opening part of the through-hole.

5. The method of mounting an electronic component according to claim 1, wherein the restricting member is a solder ball welded to the electronic component.
